(19) United States
(12) Patent Application Publication
(10) Pub. No.: US 2003/0085408 A1
(43) Pub. Date: May 8, 2003

(54) Oxygen-doped silicon carbide etch stop layer

(76) Inventors: Neng-Hui Yang, Hsin-Chu City (TW); Cheng-Yuan Tsai, Yun-Lin Hsien (TW); Hsin-Chang Wu, Taipei City (TW)

Correspondence Address: NAIPO (NORTH AMERICA INTERNATIONAL PATENT OFFICE), P.O. BOX 506, MERRIFIELD, VA, 22116, US

(21) Appl. No.: 09/682,940

(22) Filed: Nov. 2, 2001

(51) Int. Cl. H01L 31/0312; H01L 33/00

(52) U.S. Cl. 257/77; 257/102; 257/103

(57) ABSTRACT

A low-k (k<4.2) oxygen-doped SiC layer acts as an etch stop layer for dual-damascene applications. A dual-damascene structure includes: a base layer; a first dielectric layer formed on the base layer; an oxygen-doped silicon carbide etch stop layer formed on the first dielectric layer; and a second dielectric layer formed on the etch stop layer. The second dielectric layer is deposited by using a chemical vapor deposition (CVD) method. The novel oxygen-doped etch stop layer presents a lower dielectric constant (k˜4.1), better mechanical properties, and improved electrical properties.

### BACKGROUND OF INVENTION

1. Field of the Invention

The present invention relates in general to the field of integrated circuit structures, and more particularly, to an oxygen-doped silicon carbide etch stop layer fordual-damascene interconnect applications.

2. Description of the Prior Art

As the demand for faster device speeds continues to increase, fabrication and design engineers have begun implementing lower dielectric constant materials. Typically, the speed of an interconnect structure is characterized in terms of RC (resistance/capacitance) delays. Lower dielectric constant materials help to reduce inter-metal capacitance, and therefore, result in reduced delays and faster devices.

Dual damascene processeshave been widely used inthe back-end of line (BEOL) fields for fabricating high-speed logic devicesat 0.25 μ mgenerations and below. The dual damascene techniques,as known to those skilled in the art, typically include: (1) a via-first process, (2) a self-aligned process, and (3) a trench-first process.In a conventional dual-damasceneprocess, interconnect wiring lines and via plugs are defined and formed simultaneously in trenches and via holes that are etched into a stacked dielectric layer having an etch stop layer interposed between an upper low-k (low dielectric constant) film and a bottom low-k film. The low-k films are typically made of, for example, inorganic materials such as fluorosilicate (FSG), hydrogen silsesquioxane (HSQ), methyl silsesquioxane (MSQ), and organic materials such as Flare™, SiLK™, BCB (materials derived from B-stage bisbenzocyclobutane chemistry), and parylene.

In a conventional dual-damascene process, silicon nitride is usually used to form the etch stop layer. However, one of the drawbacks to using silicon nitride is its high dielectric constant (k>6.5). To improve the performance of the interconnect metallization lines, lower dielectric materials must be developed for the etch stop layer.Furumura et al. in U.S. Pat. No. 5,103,285 teach the use of silicon carbide (SiC) (k<5) as a barrier layer between a silicon substrate and a metal wiring layer. Mark et al. in U.S. Pat. No. 5,818,071 disclose the use of an amorphous SiC (a-SiC) film as a diffusion barrier to stop the migration of metal atoms between a wiring line and a dielectric layer.

The birth of the low-k silicon carbide film seems to be an effective solution to replace the prior art high-k silicon nitride etch stop layer for dual damascene applications. Unfortunately, there are still several disadvantages displayed by silicon carbide, which include: (1) a low breakdown voltage, (2)a high leakage current, and (3) low film stability. Some studies have shown that a nitrogen-doped (N-doped) SiC film has improved electrical properties. Nevertheless, N-doped SiC materials can produce amine-like compounds that result in undesirable DUV resist footing effects, as well as via blinding. Consequently, there is a strong need for a new low-k etch stop layer having improved electrical properties, as well as the ability to not affect DUV resist.

### SUMMARY OF INVENTION

It is therefore the primary objective of the present invention to provide a high performance dual-damascene structure having a novel low-k etch stop layer.

Another objective of the present invention is to provide a method for improving reliability and speed of a dual-damascene structure by taking advantage of a novel oxygen-doped silicon carbide material as an etch stop layer in a dual-damascene structure. One preferred embodiment of the present invention substantially includes: a base layer; a first dielectric layer formed on the base layer; an oxygen-doped silicon carbide etch stop layer formed on the first dielectric layer; and a second dielectric layer formed on the etch stop layer. The second dielectric layer is deposited by using a chemical vapor deposition (CVD) method.

Another preferred embodiment of the present substantially includes: a base layer having a conductive layer formed thereon; a first dielectric layer formed on the base layer; an etch stop layer formed on the first dielectric layer; a via hole formed in the first dielectric layer and the etch stop layer to thereby expose a portion of the conductive layer; a second dielectric layer formed on the etch stop layer; and a trench formed in the second dielectric layer above the via hole, the trench being used to accommodate a metal wiring. The etch stop layer is composed of oxygen-doped silicon carbide, and the second dielectric layer is formed by using a chemicalvapor deposition (CVD) process.

The advantage of the present invention over the prior art is that the oxygen-doped etch stop layer has improved electrical properties, including: (1)a higherbreakdown voltage, (2)lower leakage currents, and (3) both greater film stability, and improved mechanical properties in terms of hardness. Moreover, the oxygen-doped etch stop layer displays a dielectric constant that is less than 4.2, which improves the electrical performance of devices.

These and other objectives of the present invention will no doubt become obvious to those of ordinary skill in the art after reading the following detailed description of the preferred embodiment, which is illustrated in the various tables, figures and drawings.

### BRIEF DESCRIPTION OF DRAWINGS

FIG. 1 is a schematic, cross-sectional diagram depicting a stacked dielectric layer after forming a dual-damascene structure according to the present invention.

Table 1 illustrates electrical properties of a 500 Å thick SiOₓC_{y} layer compared to a single layer of SiC.

### DETAILED DESCRIPTION

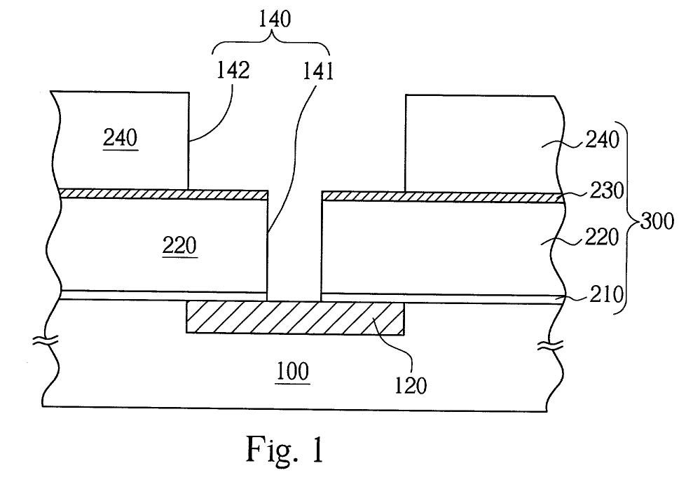

Please refer to FIG. 1. FIG. 1 is a schematic, cross-sectional diagram depicting a stacked dielectric layer 300 after forming a dual-damascene structure 140 according to the present invention. As shown in FIG. 1, the stacked dielectric layer 300 is formed over a base layer 100, which may be an underlying interlayer dielectric (ILD) or a substrate. A barrier layer 210, which is used to prevent diffusion of metals, is interposed between the base layer 100 and the stacked dielectric layer 300. The dielectric layer 300 comprises a first dielectric layer 220 formed over the barrier layer 210, an etch stop layer 230 formed over the first dielectric layer 220, and a second dielectric layer 240 formed over the etch stop layer 230. Preferably, the etch stop layer 230 has a thickness of about 500 angstroms (Å). The dual-damascene structure 140 comprises a via opening 141 through the etch stop layer 230, the first dielectric layer 220 and the barrier layer 210 to an underlying metal structure 120, which is previously formed on the base layer 100, and a trench opening 142 formed in the second dielectric layer above the via opening 141.

As alluded to previously, the dual-damascene structure 140 may be created by utilizing a via-first process, a partial-via process, a self-aligned process, a trench-first process, or the like. Since the method adopted to create a dual-damascene structure 140 is not a topic of major concern of the present invention, and is well known to those skilled in the art, details of the process steps are omitted in the following discussion. The process steps adopting a trench-first scheme, for example, include: (1) depositing/spin-coating a first dielectric layer on a base layer; (2) forming an etch stop layer over the first dielectric layer; (3) depositing a second dielectric layer over the etch stop layer; (4) defining a trench pattern in the second dielectric layer by way of a photo-resist via mask; (5) forming a photo resist mask in the trench to define the via pattern; (6) etching through the via pattern and the etch stop layer with a reactive ion etch (RIE) process to exposing a wire in the base layer, and (7) stripping the photo-resist via mask.

The first dielectric layer 220 may be made from a material selected from fluorinated silicon glass, (FSG), hydrogensilsesquioxane (HSQ), methyl silsesquioxane (MSQ), black diamond, Coral, porous silica, amorphous fluorocarbon polymers, fluorinated polyimide, PTFE, poly(arylene ether), benzocyclobutene, SiLK™, FLARE™, and the like. The second dielectric layer 240 may be made from a material selected from fluorinated silicon glass, (FSG), hydrogensilsesquioxane (HSQ), methyl silsesquioxane (MSQ), black diamond, Coral, porous silica, amorphous fluorocarbon polymers, fluorinated polyimide, PTFE, poly(arylene ether), benzocyclobutene, SiLK™, FLARE™, and the like. In the preferred embodiment of the present invention, the first dielectric layer 220 and the second dielectric layer 240 are both made of a material with a dielectric constant of less than 3.2.

Preferably, the second dielectric layer 240 is formed by using a chemical vapor deposition (CVD) process that utilizes methylsilane as a precursor. The precusor may be methylsilane (Si(CH₃)H₃), 2-methylsilane (Si(CH₃)₂H₂), 3-methylsilane (Si (CH₃)₃H) or 4-methylsilane (Si(CH₃)₄). In this way, the etch stop layer 230 and the second dielectric layer 240 have a substantially similar crystalline film structure, thus improving the adhesion between the etch stop layer 230 and the second dielectric layer 240. More preferably, the first dielectric layer 220 and the second dielectric layer 240 are formed by using a chemical vapor deposition (CVD) process that utilizes methylsilane as a precursor. The precusor may be methylsilane (Si(CH₃) H₃), 2-methylsilane (Si(CH₃)₂H₂), 3-methylsilane (Si(CH₃)₃H) and 4-methylsilane (Si(CH₃)₄). In this case, the quality of adhesion at the interface between the first dielectric layer 220 and the etch stop layer 230, and at the interface between the second dielectric layer 240 and the etch stop layer 230, is improved.

The metal structure 120 is made of copper and is formed by using physical vapor deposition (PVD), electroplating, sputtering or an electron beam evaporation technique.

The etch stop layer 230 according to the present invention is deposited by using a plasma enhanced CVD (PECVD) process. Parameters of the PECVD process, such as flow rate, operating pressure, temperature and reaction time will depend on the CVD apparatus, or on special process requirements. Examples of PECVD parameters for depositing the oxygen-doped SiC layer 230 include, a 3-methylsilane (Si(CH₃)₃H) flow rate of about 600 sccm (standard cubic centimeters per minute), an oxygen flow rate of about 30 sccm, a high frequency radio frequency (HFRF) of about 150 watts, an operational pressure of 0.5 to 5 Torr(preferably 2 Torr), and a temperature of 350 to 450° C. (preferably 400° C.). In other embodiments of the present invention, Si(CH₃)₃, Si(CH₂)₂ or Si(CH₃)₃H can be used as the precursor gas.

TABLE 1

| | O₂-doped SiC (500 Å | Undoped SiC (500 |
|---|---|---|
| | SiOₓC_{y}) | Å SiC) |
| Dielectric constant, k | 4.1 | 4.5 |
| Breakdown voltage | 5.0 | 3.5 |
| (MV/cm) | | |
| Leakage (A/cm² | 1.01E-9 | 1.3E-8 |
| @ 1 MV/cm) | | |
| Refraction index, RI | 1.84 | 1.88 |
| Hardness (Gpa) | >10 | 5-6 |
| Uniformity (U% | 1.43 | 2.05 |
| @ 1 sigma) | | |

Please refer to Table.1, which illustrates the electrical properties of a 500 Å thick SiOₓC_{y} layer as compared to a single layer of SiC. As shown in Table.1, the oxygen-doped SiC layer of the present invention has an improved dielectric constant of about 4.1, which is lower than that of an undoped SiC layer. The dielectric constant of an undoped SiC layer is about 4.5. Additionally, the oxygen-doped SiC layer also presents a high breakdown voltage of about 5.0 MV/cm, and a low leakage current of about 1.01E-9 A/cm². In comparison, the undoped SiC layer presents a lower breakdown voltage of about 3.5 MV/cm, and a higher leakage current of about 1.3E-8 A/cm². Moreover, the oxygen-doped SiC layer presents better mechanical properties in terms of hardness (>10 Gpa) than that of the undoped SiC layer (5 to 6 Gpa).

In short, it is the key feature of the present invention to utilize a low-k (k<4.2) oxygen-doped SiC layer as an etch stop layer for dual-damascene applications. The advantages of the present invention over the prior art are that the oxygen-doped etch stop layer has improved electrical properties, as well as mechanical properties (in terms of hardness). These improved electrical properties include: (1)a higherbreakdown voltage, (2)lower leakage current, and (3)greater film stability. Higher speeds and better performance are thus achieved.

Those skilled in the art will readily observe that numerous modification and alterations of the device may be made while retaining the teachings of the invention. Accordingly, the above disclosure should be construed as limited only by the metes and bounds of the appended claims.

What is claimed is:

1. An integrated circuit comprising:
a base layer;
a first dielectric layer formed on the base layer;
an oxygen-doped silicon carbide etch stop layer formed on the first dielectric layer; and
a second dielectric layer formed on the etch stop layer.

2. The integrated circuit according to claim 1 wherein the thickness of the etch stop is about 500 angstroms (Å).

3. The integrated circuit according to claim 1 wherein the etch stop layer is deposited by using a plasma-enhanced chemical vapor deposition (PECVD) process.

4. The integrated circuit according to claim 1 wherein both the first dielectric layer and the second dielectric layer have a dielectric constant of less than 3.2.

5. The integrated circuit according to claim 1 wherein the second dielectric layer is formed by using a chemical vapor deposition (CVD) process.

6. The integrated circuit according to claim 1 wherein the second dielectric layer is made from a methylsilane precursor.

7. The integrated circuit according to claim 6 wherein the methylsilane precursor is selected from a group consisting of methylsilane (Si(CH₃)H₃), 2-methylsilane (Si(CH₃)₂H₂), 3-methylsilane (Si(CH₃)₃H) and 4-methylsilane (Si(CH₃)₄).

8. The integrated circuit according to claim 1 wherein the etch stop layer has a dielectric constant of about 4.1.

9. The integrated circuit according to claim 1 wherein the etch stop layer has a breakdown voltage of about 5.0 MV/cm at a thickness of 500 Å.

10. A dual-damascene structure comprising:
a base layer having a conductive layer formed thereon;
a first dielectric layer formed on the base layer;
an etch stop layer formed on the first dielectric layer;
a via hole formed in the first dielectric layer and the etch stop layer to expose a portion of the conductive layer;
a second dielectric layer formed on the etch stop layer; and
a trench formed in the second dielectric layer above the via hole, the trench being used to accommodate a metal wiring;
wherein the etch stop layer is composed of oxygen-doped silicon carbide, and the second dielectric layer is formed by using a chemicalvapor deposition (CVD) process.

11. The dual-damascene structure according to claim 10 wherein the etch stop layer is deposited by using a plasma-enhanced chemical vapor deposition (PECVD) process.

12. The dual-damascene structure according to claim 10 wherein the second dielectric layer is made from a methylsilane precursor.

13. The dual-damascene structure according to claim 12 wherein the methylsilane precursor is selected from a group consisting of methylsilane (Si (CH₃)H₃), 2-methylsilane (Si(CH₃)₂H₂), 3-methylsilane (Si(CH₃)₃H) and 4-methylsilane (Si(CH₃)₄).

14. The dual-damascene structure according to claim 10 wherein the etch stop layer has a dielectric constant of about 4.1.

15. The dual-damascene structure according to claim 10 wherein the etch stop layer has a breakdown voltage of about 5.0 MV/cm at a thickness of 500 Å.
